(19) United States
(12) Patent Application Publication
(10) Pub. No.: US 2009/0166762 A1
(43) Pub. Date: Jul. 2, 2009

(54) MONITORING PATTERN OF SEMICONDUCTOR DEVICE AND METHOD FOR FABRICATING THE SAME

(76) Inventor: Je-Sik Ou, Gwanak-gu (KR)

Correspondence Address: SHERR & VAUGHN, PLLC, 620 HERNDON PARKWAY, SUITE 200, HERNDON, VA, 20170, US

(21) Appl. No.: 12/120,274

(22) Filed: May 14, 2008

(30) Foreign Application Priority Data
Dec. 28, 2007 (KR) 10-2007-0137191

(51) Int. Cl. H01L 29/00; H01L 21/425

(52) U.S. Cl. 257/408; 438/517; 257/E21.473; 257/E29.001

(57) ABSTRACT

A monitoring pattern of a semiconductor device and a method for fabricating the same, capable of increasing an area utilization rate. The monitoring pattern of a semiconductor device includes a gate electrode formed on a semiconductor substrate provided with an isolation film, a spacer formed on one sidewall of the gate electrode, an LDD region formed on the surface of the semiconductor substrate, a salicide formed over the entire surface of the semiconductor substrate in a region other than the region provided by the spacer, an interlayer dielectric film formed over the entire surface of the semiconductor substrate, contacts, each passing through the interlayer dielectric film arranged on the salicide, and a metal line arranged on the interlayer dielectric film, while being connected to the contacts.

The present application claims priority under 35 U.S.C. 119 to Korean Patent Application No. 10-2007-0137191, filed on (Dec. 26, 2008), which is hereby incorporated by reference as if fully set forth herein.

### BACKGROUND

Generally, integrated circuits have gradually been made smaller. This miniaturization in integrated circuits inevitably involves reduction in sizes of constituent components thereof. Semiconductor processing currently used to fabricate devices such as transistors, diodes, MIMs and capacitors necessarily requires contacts and metal lines to connect the devices. For this reason, in cases where device defects occur, to ascertain whether the defects are practically attributed by devices, or by contacts or metal lines connecting the same, monitoring patterns are being realized, together with the devices, etc.

In order to realize great number of devices in a limited small area, however, monitoring patterns must be made as small as possible. In particular, when there occur device defects associated with the recent trend toward reductions in length of gates and in area of sources/drains of transistors, separate monitoring patterns for the contact of the gate poly and the contact of the source/drain are required to ascertain whether or not the device defects are caused by defects in contacts of the gate poly and the source/drain. Such separate monitoring patterns have problems of requiring a large realization area and taking a longer time to separately test the monitoring patterns and then to obtain the results.

### SUMMARY

Embodiments relate to a semiconductor device, and more particularly, to a monitoring pattern of a semiconductor device and a method for fabricating the same, that can result in an increase in an area utilization rate.

Embodiments relate to a monitoring pattern of a semiconductor device that can include at least one of the following: a gate electrode formed on and/or over a semiconductor substrate provided with an isolation film; a spacer formed on and/or over one sidewall of the gate electrode; an LDD region formed on and/or over the surface of the semiconductor substrate; a salicide formed on and/or over the entire surface of the semiconductor substrate in a region other than the region provided by the spacer; an interlayer dielectric film formed on and/or over the entire surface of the semiconductor substrate; contacts, each passing through the interlayer dielectric film arranged on and/or over the salicide; and a metal line arranged on and/or over the interlayer dielectric film, while being connected to the contacts.

In accordance with embodiments, the LDD region can be formed in a portion of the semiconductor substrate adjacent to the other sidewall of the gate electrode provided with no spacer. The contacts can be connected to the gate electrode and the LDD region, respectively.

The gate electrode can be composed of non-doped polysilicon. The silicide can be composed of Tco/Ti/TiN. The gate electrode can be formed on and/or over the isolation film. The salicide can be formed in a portion provided on and/or over the gate electrode, a portion provided on and/or over the other sidewall of the gate electrode on and/or over which no spacer is formed and a portion provided on and/or over the LDD region. The metal line can be connected to the contact formed in the LDD region of another gate electrode formed on and/or over the semiconductor substrate.

Embodiments relate to a method for fabricating a monitoring pattern of a semiconductor device that can include at least one of the following steps: forming a gate electrode on and/or over a semiconductor substrate provided with an isolation film; forming an LDD region on and/or over the surface of the semiconductor substrate; forming a spacer formed on and/or over a first sidewall of the gate electrode; forming a salicide on and/or over the entire surface of the semiconductor substrate in a region other than the region provided by the spacers; forming an interlayer dielectric film on and/or over the entire surface of the semiconductor substrate; forming contacts such that the contacts pass through the interlayer dielectric film arranged on and/or over the salicide; and forming a metal line on and/or over the interlayer dielectric film such that the metal line is connected to the contacts.

In accordance with embodiments, in the step of forming the LDD region, the LDD region can be formed in a portion of the semiconductor substrate adjacent to the sidewall of the gate electrode provided with no spacer. In the step of forming the contacts, the contacts can be formed such that the contacts are connected to the gate electrode and the LDD region, respectively. In the step of forming the gate electrode, the gate electrode can be formed using non-doped polysilicon and can be formed on and/or over the isolation film. The step of forming the salicide can include: forming a first salicide on a second sidewall of the gate electrode; and forming a second salicide in portions provided on and/or over the gate electrode and the LDD region. The first and second salicides can be formed by sputtering Tco/Ti/TiN using a sputter.

In accordance with embodiments, in the step of forming the metal line, the metal line can be formed such that the metal line is connected to the contacts formed in the LDD region of another gate electrode formed on and/or over the semiconductor substrate. The step of forming the spacer on and/or over the first sidewall of the gate electrode can include: forming spacers on and/or over first and second sidewalls of the gate electrode; and removing the spacer formed on and/or over the second sidewall of the gate electrode through etching using the photoresist pattern. The spacer formed on and/or over the second sidewall of the gate electrode can be removed by dry etching.

### DRAWINGS

Example FIG. 1 illustrates a monitoring pattern of a semiconductor device, in accordance with embodiments.

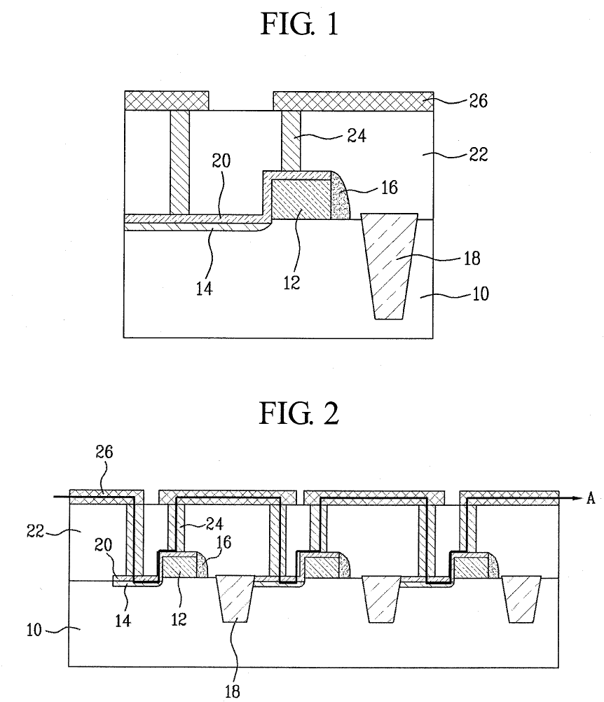

Example FIG. 2 illustrates a chain structure of a semiconductor device, in accordance with embodiments.

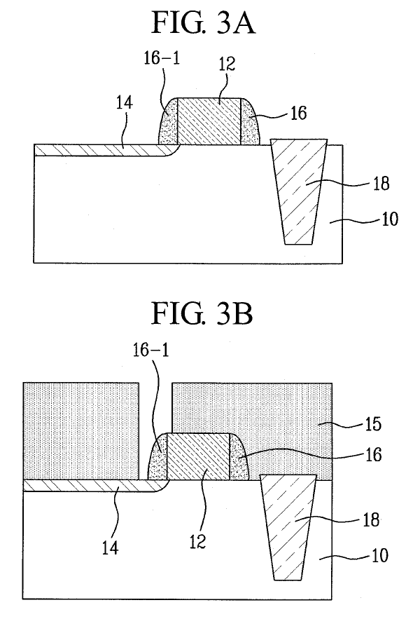

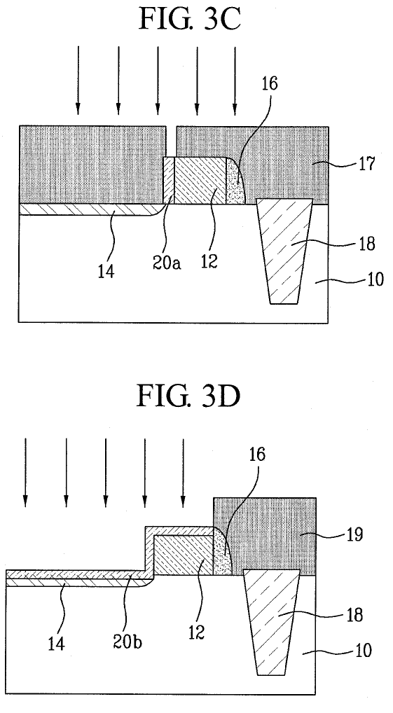

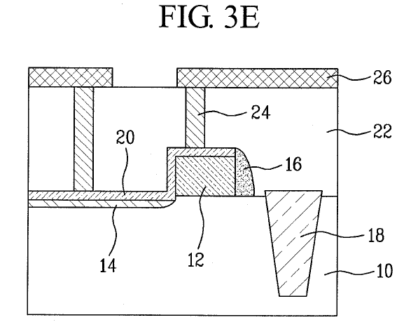

Example FIGS. 3A to 3E illustrate a method for fabricating the semiconductor device, in accordance with embodiments.

### DESCRIPTION

As illustrated in example FIG. 1, the monitoring pattern of a semiconductor device can include gate electrode 12 formed on and/or over semiconductor substrate 10 provided with isolation film 18. Spacer 16 can be formed on and/or over one sidewall of gate electrode 12. LDD region 14 can be formed in semiconductor substrate 10 in a region adjacent the other sidewall of gate electrode 12 on and/or over which no spacer is formed. Salicide layer 20 can be formed on and/or over the upper most surface of gate electrode 12, the other sidewall of gate electrode 12 on and/or over which no spacer is formed, and LDD region 14. Interlayer dielectric film 22 can be formed on and/or over the entire surface of semiconductor substrate 10, including salicide layer 20, isolation film 18 and spacer 16. Contacts 24 can be formed extending through interlayer dielectric film 22 and on and/or over salicide 20. Metal line 26 can be formed on and/or over interlayer dielectric film 22 and in contact with contacts 24. Based on the aforementioned configuration, by applying an electric current to the monitoring pattern, contacts of the gate electrode, a source/drain region and the metal line can be measured simultaneously.

As illustrated in example FIG. 2, the semiconductor device monitoring pattern in accordance with embodiments can have a single pattern structure as illustrated in example FIG. 1, but also a chain-shaped pattern in which gate electrodes 12 are connected to each other through salicide layer 20, contacts 24 and metal line 26. Current flow through such a chain-shaped monitoring pattern is represented by line A. Moreover, the semiconductor device monitoring pattern in accordance with embodiments can have a structure in which gate electrode 12 is formed on and/or over isolation film 18.

Accordingly, the semiconductor device monitoring pattern in accordance with embodiments can realize a monitoring pattern in various regions, thus securing an increased effective area due to a reduced realization area of the monitoring pattern. In addition, device and test patterns can be variably embedded in the secured effective area, thus increasing an area utilization degree. Even still, when device defects occur, as opposed to employing separate tests on two patterns for detection of the defects, embodiments conducts defect tests simultaneously on only a single pattern. This eliminates the necessity of conducting separate tests, which in turn, result in a reduction in time to obtain test results and then solve the defect problems.

As illustrated in example FIG. 3A, a method for fabricating the semiconductor device monitoring pattern in accordance with embodiments can include forming isolation film 18 in a predetermined region of semiconductor device 10. Subsequently, a well can then be formed in substrate 10 through a well-ion implantation process. A gate oxide film and a gate conductive film can then be sequentially formed on and/or over substrate 10 and then patterned to form gate electrode 12. Non-doped polysilicon can be used for the gate conductive film. Alternatively, gate electrode 12 can be formed on and/or over isolation film 18. Lightly doped drain (LDD) region 14 can then be formed ion semiconductor substrate 10 under one sidewall of gate electrode 12. Spacers 16, 16-1 can then be formed on and/or over both sidewalls of gate electrode 12. Spacers 16, 16-1 can be composed of an oxide such as SiO₂.

As illustrated in example FIG. 3B, the resulting structure provided on and/or over substrate is exposed to light and developed to form photoresist pattern 15 though which spacer 16-1 formed on and/or over LDD region 14 is exposed. Through dry etching using the photoresist pattern 15 as a mask, spacer 16-1 is removed.

As illustrated in example FIG. 3C, after photoresist pattern 15 is removed, first TEOS film 17 can be formed on and/or over the resulting structure through which exposes one sidewall of gate electrode 12 where spacer 16-1 was removed. First salicide layer 20a, which can be composed of Tco/Ti/TiN, can then be formed on the exposed sidewall of gate electrode 12 using a sputtering process.

As illustrated in example FIG. 3D, after removal of TEOS film 17, second TEOS film 19 can be formed on and/or over the resulting structure of substrate 10 through exposure to light and development, such that second TEOS film 19 covers spacer 16, while exposing gate electrode 12 and LDD region 14. Second salicide layer 20b, which can be composed of Tco/Ti/TiN, can then be formed on and/or over the exposed sidewall of gate electrode 12 and also LDD region 14 using a sputtering process.

As illustrated in example FIG. 3E, the removal of second TEOS film 19, interlayer dielectric film 22 is formed on and/or over the resulting structure and then subjected to surface-planarization. Predetermined portions of interlayer dielectric film 22 can then be selectively etched to form contacts 24 connected to gate electrode 12 and LDD region 14, respectively. Metal lines 26 can then be formed on and/or over interlayer dielectric film 22 including contacts 24 such that gate electrodes 12 are connected to each other through salicide layer 20, contacts 24 and metal lines 26.

As apparent from the fore-going, according to the monitoring pattern for semiconductor devices and the method for fabricating the same, a gate electrode and an LDD region can be connected to each other in a single- or chain shaped in a minimized area. As a result, it is possible to realize a monitoring pattern in various regions and secure an increased effective area due to reduced realization area of the monitoring pattern. Furthermore, device and test patterns can be variably embedded in the secured effective area, thus increasing an area utilization rate. Even still, when device defects occur, defect tests can be simultaneously preformed on only the single pattern, thereby eliminating the necessity of separately performing tests on two patterns, and thus, taking a shorter time to obtain test results and solve the defect problems.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A monitoring pattern of a semiconductor device comprising:
a gate electrode formed on a semiconductor substrate provided with an isolation film;
a spacer formed on one sidewall of the gate electrode;
an LDD region formed in the semiconductor substrate;
a salicide layer formed on the semiconductor substrate in a region other than the region occupied by the spacer;
an interlayer dielectric film formed on the semiconductor substrate including the salicide layer, the isolation film and the spacer;
contacts extending through the interlayer dielectric film and on the salicide layer; and
a metal line formed on the interlayer dielectric film and connected to the contacts.

2. The monitoring pattern of claim 1, wherein the LDD region is formed in a portion of the semiconductor substrate adjacent to an exposed sidewall of the gate electrode provided with no spacer.

3. The monitoring pattern of claim 1, wherein the contacts are connected to the gate electrode and the LDD region, respectively.

4. The monitoring pattern of claim 1, wherein the gate electrode is formed of non-doped polysilicon.

5. The monitoring pattern of claim 1, wherein the silicide is formed of Tco/Ti/TiN.

6. The monitoring pattern of claim 1, wherein the gate electrode is formed on the isolation film.

7. The monitoring pattern of claim 1, wherein the metal line is connected to the contact formed in the LDD region of another gate electrode formed on the semiconductor substrate.

8. The monitoring pattern of claim 2, wherein the salicide layer is formed on the upper most surface of the gate electrode, on the exposed sidewall of the gate electrode on which no spacer is formed, and on the LDD region.

9. The monitoring pattern of claim 8, wherein the contacts are connected to the salicide layer formed on the gate electrode and the LDD region, respectively.

10. A method for fabricating a monitoring pattern of a semiconductor device comprising:
forming a gate electrode on a semiconductor substrate provided with an isolation film; and then
forming an LDD region in the semiconductor substrate; and then
forming a spacer on a first sidewall of the gate electrode; and then
forming a salicide layer over the semiconductor substrate in a region other than the region occupied by the spacer; and then
forming an interlayer dielectric film on the semiconductor substrate including the salicide layer, the isolation film and the spacer; and then
forming contacts extending through the interlayer dielectric film and on the salicide layer; and then
forming a metal line on the interlayer dielectric film and connected to the contacts.

11. The method according to claim 10, wherein forming the LDD region comprises:
forming the LDD region in a portion of the semiconductor substrate adjacent to an exposed sidewall of the gate electrode provided with no spacer.

12. The method according to claim 10, wherein forming the contacts comprises:
forming the contacts such that the contacts are connected to the gate electrode and the LDD region, respectively.

13. The method according to claim 10, wherein forming the gate electrode is performed by forming the gate electrode using non-doped polysilicon.

14. The method according to claim 10, wherein forming the salicide is performed by forming the salicide using Tco/Ti/TiN.

15. The method according to claim 10, wherein forming the gate electrode is performed by forming the gate electrode on the isolation film.

16. The method according to claim 10, wherein forming the metal line is performed by forming the metal line such that the metal line is connected to the contacts formed in the LDD region of an adjacent gate electrode formed on the semiconductor substrate.

17. The method according to claim 10, wherein forming the spacer comprises:
forming spacers on first and second sidewalls of the gate electrode; and then
removing the spacer formed on the second sidewall of the gate electrode through an etching process using a photoresist pattern.

18. The method according to claim 17, wherein the spacer formed on the second sidewall of the gate electrode is removed by dry etching.

19. The method according to claim 10, wherein the step of forming the salicide layer comprises:
forming a first salicide layer on the second sidewall of the gate electrode; and then
forming a second salicide layer on the gate electrode and the LDD region.

20. The method according to claim 19, wherein the first and second salicides are formed using a sputtering process.
